(19) United States
(12) Patent Application Publication
(10) Pub. No.: US 2011/0111604 A1
(43) Pub. Date: May 12, 2011

(54) PLASMA SURFACE TREATMENT TO PREVENT PATTERN COLLAPSE IN IMMERSION LITHOGRAPHY

(76) Inventors: Eui Kyoon Kim, Campbell, CA (US); Deenesh Padhi, Sunnyvale, CA (US); Huixiong Dai, San Jose, CA (US); Mehul Naik, San Jose, CA (US); Martin Jay Seamons, San Jose, CA (US); Bok Hoen Kim, (US)

(21) Appl. No.: 13/007,963

(22) Filed: Jan. 17, 2011

Related U.S. Application Data
(63) Continuation of application No. 11/877,559, filed on Oct. 23, 2007, now abandoned.

(51) Int. Cl. H01L 21/31

(52) U.S. Cl. 438/763; 257/E21.24

(57) ABSTRACT

The present invention comprises a method of reducing photoresist mask collapse when the photoresist mask is dried after immersion development. As feature sizes continue to shrink, the capillary force of water used to rinse a photoresist mask approaches the point of being greater than adhesion force of the photoresist to the ARC. When the capillary force exceeds the adhesion force, the features of the mask may collapse because the water pulls adjacent features together as the water dries. By depositing a hermetic oxide layer over the ARC before depositing the photoresist, the adhesion force may exceed the capillary force and the features of the photoresist mask may not collapse.

### CROSS REFERENCE TO RELATED APPLICATIONS

This application is a continuation U.S. patent application Ser. No. 11/877,559, filed Oct. 23, 2007, which is herein incorporated by reference.

### BACKGROUND OF THE INVENTION

1. Field of the Invention

Embodiments of the present invention generally relate to a method for preventing pattern collapse in immersion lithography.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 90 nm and even 65 nm feature sizes, and tomorrow's facilities soon will be producing devices having even smaller feature sizes such as 45 nm or smaller.

As the feature sizes of integrated circuits decrease, so do the features of the photoresist mask used to pattern the features into the integrated circuit. Photoresist may be deposited, exposed, and then developed to create the photoresist mask. When the development is immersion development, the developing solution may be rinsed from the integrated circuit with deionized water. With smaller features sizes, the adhesion force of the photoresist mask to an antireflective coating (ARC) or even an adhesion promoting layer deposited on the ARC layer may approach the point where the capillary force of the drying water exceeds the adhesion force. When the capillary force exceeds the adhesion force, the pattern may collapse. When the pattern collapses, the integrated circuit will be defective because effective etching of features into the integrated circuit will not be performed.

Therefore, there is a need in the art for a method of increasing the adhesion of the photoresist to the integrated circuit and reducing pattern collapsing in integrated circuits.

### SUMMARY OF THE INVENTION

The present invention generally comprises a method of reducing photoresist mask collapse when the photoresist mask is dried after immersion development. In one embodiment, a method of reducing photoresist mask collapse during photoresist mask drying comprises depositing a hermetic oxide layer on an antireflective coating disposed over a substrate, depositing an adhesion promoting layer on the hermetic oxide layer, depositing a photoresist layer over the hermetic oxide layer, pattern exposing the photoresist, immersion developing the photoresist to create a photoresist mask, and drying the photoresist mask.

In another embodiment, a method of reducing photoresist mask collapse during photoresist mask drying comprises depositing a hermetic oxide layer on an antireflective coating disposed over a substrate, depositing a photoresist layer on the hermetic oxide layer, pattern exposing the photoresist, immersion developing the photoresist to create a photoresist mask having features less than about 45 nm in width, and drying the photoresist mask.

In another embodiment, a method of patterning an antireflective coating comprises depositing a hermetic oxide layer on the antireflective coating, exposing the hermetic oxide layer to hexemethyldisilizane to deposit an adhesion promoting layer on the hermetic oxide layer, depositing a photoresist layer on the hermetic oxide layer exposed to the hexemethyldisilizane, exposing and developing the photoresist to create a mask, and patterning the hermetic oxide layer and the antireflective coating using the mask.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of an apparatus that may be used to practice embodiments of the invention.

FIGS. 2A-2D are schematic views of an integrated circuit 200 having a photoresist mask formed thereon at various stages of processing according to one embodiment of the invention.

FIGS. 3A-3D are schematic views of an integrated circuit 300 having a photoresist mask formed thereon at various stages of processing.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention comprises a method of reducing photoresist mask collapse when the photoresist mask is dried after immersion development. As feature sizes continue to shrink, the capillary force of water used to rinse a photoresist mask approaches the point of being greater than adhesion force of the photoresist to the ARC. When the capillary force exceeds the adhesion force, the features of the mask may collapse because the water pulls adjacent features together as the water dries. By depositing a hermetic oxide layer over the ARC before depositing the photoresist, the adhesion force exceeds the capillary force and the features of the photoresist mask do not collapse.

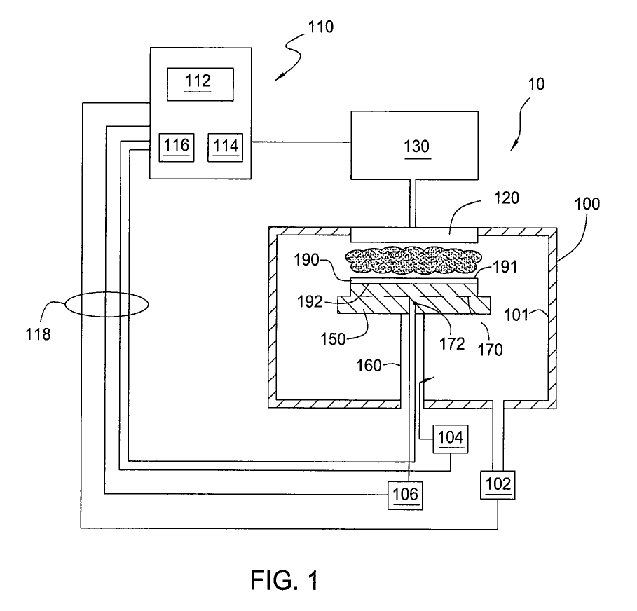

FIG. 1 illustrates schematic representation of a wafer processing system 10 that may be used to deposit hermetic oxide layers, ARC layers, and amorphous carbon layers. This system generally includes a process chamber 100, a gas panel 130, a control unit 110, and other hardware components, such as power supplies, vacuum pumps, etc. that are known in the art to be used to manufacture integrated circuit components. Examples of the system 10 include CENTURA® systems, PRECISION 5000® systems, and PRODUCER™ systems, all of which are commercially available from Applied Materials Inc., of Santa Clara, Calif.

The process chamber 100 generally includes a support pedestal 150, which is used to support a substrate, such as a semiconductor wafer 190. This pedestal 150 may typically be moved in a vertical direction inside the chamber 100 using a displacement mechanism 160. Depending on the specific process, the wafer 190 may be heated to a desired temperature by an embedded heating element 170 within pedestal 150. For example, the pedestal 150 may be resistively heated by applying an electric current from an AC supply 106 to the heating element 170, which then heats the wafer 190. A temperature sensor 172, such as a thermocouple, for example, may be embedded in the wafer support pedestal 150 in order to monitor the temperature of the pedestal 150 through cooperative interaction with a process control system (not shown). The temperature read by the thermocouple may be used in a feedback loop to control the power supply 106 for the heating element 170 such that the wafer temperature can be maintained or controlled at a desired temperature that is suitable for the particular process application. Alternatively, the pedestal 150 may utilize alternative heating and/or cooling configurations known in the art, such as, plasma and/or radiant heating configurations or cooling channels (not shown).

A vacuum pump 102 may be used to evacuate the process chamber 100 and to maintain the desired gas flows and dynamic pressures inside the chamber 100. A showerhead 120, through which process gases may be introduced into the chamber 100, may be located above the wafer support pedestal 150. The showerhead 120 may generally be connected to a gas panel 130, which controls and supplies various gases used in different steps of the process sequence.

The showerhead 120 and wafer support pedestal 150 may also form a pair of spaced electrodes. Therefore, when an electric field is generated between these electrodes, the process gases introduced into the chamber 100 by the showerhead 120 may be ignited into a plasma, assuming that the potential between the spaced electrodes is sufficient to initiate and maintain the plasma. Typically, the driving electric field for the plasma is generated by connecting the wafer support pedestal 150 to a source of radio frequency (RF) power 104 through a matching network (not shown). Alternatively, the RF power source and matching network may be coupled to the showerhead 120, or coupled to both the showerhead 120 and the wafer support pedestal 150.

Plasma enhanced chemical vapor deposition (PECVD) techniques generally promote excitation and/or disassociation of the reactant gases by the application of the electric field to a reaction zone near the substrate surface, creating a plasma of reactive species immediately above the substrate surface. The reactivity of the species in the plasma reduces the energy required for a chemical reaction to take place, in effect lowering the required temperature for such PECVD processes.

In embodiments of the invention, amorphous carbon layer deposition may be accomplished through plasma enhanced thermal decomposition of a hydrocarbon compound, such as propylene (C₃H₆). Propylene may be introduced into the process chamber 100 under the control of the gas panel 130. The hydrocarbon compound may be introduced into the process chamber as a gas with a regulated flow through the showerhead 120.

Proper control and regulation of the gas flows through the gas panel 130 may be conducted by one or more mass flow controllers (not shown) and a control unit 110 such as a computer. The showerhead 120 allows process gases from the gas panel 130 to be uniformly distributed and introduced into the process chamber 100 proximate the surface of the wafer 190. Illustratively, the control unit 110 may include a central processing unit (CPU) 112, support circuitry 114, and various memory units containing associated control software 116 and/or process related data. Control unit 110 may be responsible for automated control over various steps required for wafer processing, such as wafer transport, gas flow control, temperature control, chamber evacuation, and other processes known in the art to be controlled by an electronic controller. Bi-directional communications between the control unit 110 and the various components of the apparatus 10 may be handled through numerous signal cables collectively referred to as signal buses 118, some of which are illustrated in FIG. 1.

The heated pedestal 150 used in the present invention may be manufactured from aluminum, and may include a heating element 170 embedded at a distance below the wafer support surface 192 of the pedestal 150. The heating element 170 may be manufactured from a nickel-chromium wire encapsulated in an INCOLOY® sheath tube. By properly adjusting the current supplied to the heating element 170, the wafer 190 and the pedestal 150 may be maintained at a relatively constant temperature during wafer preparation and film deposition processes. Proper adjustment of the current may be accomplished through a feedback control loop, in which the temperature of the pedestal 150 is continuously monitored by the temperature sensor 172 embedded in the pedestal 150. Information may be transmitted to the control unit 110 via a signal bus 118, which may respond by sending the necessary signals to the heater power supply 106. Adjustment may subsequently be made in the power supply 106 so as to maintain and control the pedestal 150 at a desirable temperature a temperature that is appropriate for the specific process application). Therefore, when the process gas mixture exits the showerhead 120 above the wafer 190, plasma enhanced thermal decomposition of the hydrocarbon compound occurs at the surface 191 of the heated wafer 190, resulting in a deposition of an amorphous carbon layer on the wafer 190.

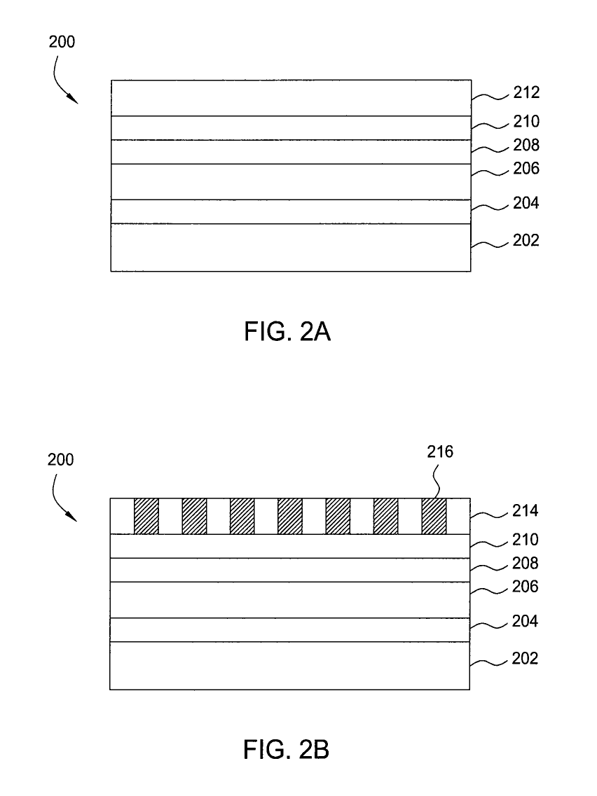

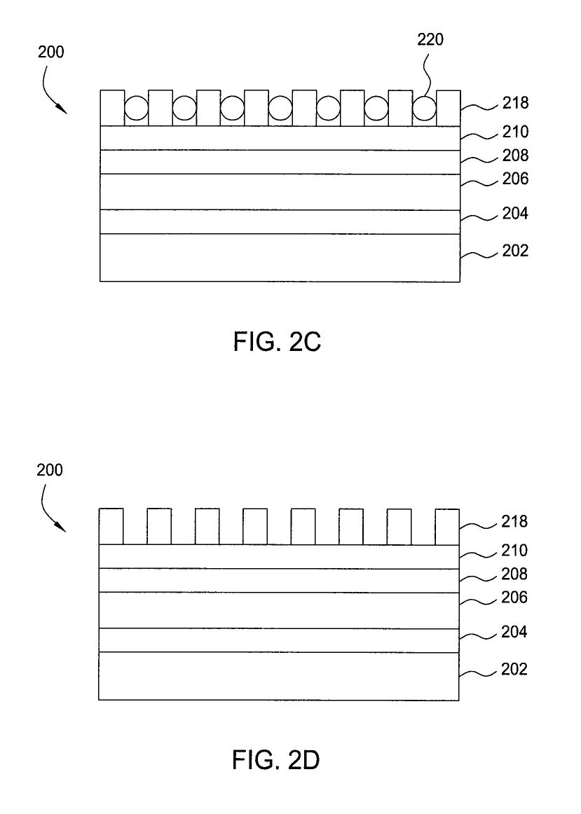

FIGS. 2A-2D are schematic views of an integrated circuit 200 having a photoresist mask formed thereon at various stages of processing according to one embodiment of the invention. As shown in FIG. 2A, the integrated circuit 200 may comprise a substrate 202. In general, the substrate 202 refers to any workpiece on which processing is performed. The substrate 202 may be part of a larger structure (not shown), such as a shallow trench isolation (STI) structure, a gate device for a transistor, a DRAM device, or a dual damascene structure. Depending on the specific stage of processing, the substrate 202 may correspond to a silicon substrate, or other material layer that has been formed on the substrate. FIG. 2A, for example, illustrates a cross-sectional view of an integrated circuit 200, having a material layer 204 that has been conventionally formed thereon. The material layer 204 may be an oxide (e.g., SiO₂). In general, the substrate 202 may include a layer of silicon, silicides, metals, or other materials. FIG. 2A illustrates one embodiment in which the substrate 202 is silicon having a material layer 204 of silicon dioxide formed thereon.

An amorphous carbon layer 206 may be deposited on the material layer 204. The amorphous carbon layer 206 may be formed from a gas mixture of a hydrocarbon compound and an inert gas such as Argon (Ar) or helium (He). The hydrocarbon compound has a general formula CₓH_{y} where x has a range of between 2 and 10 and y has a range of between 2 and 22. For example, propylene (C₃H₆), propyne (C₃H₄), propane (C₃H₈), butane (C₄H₈), butylene (C₄H₈), butadiene (C₄H₆), acetelyne (C₂H₂), pentane, pentene, pentadiene, cyclopentane, cyclopentadiene, benzene, toluene, alpha terpinene, phenol, cymene, norbornadiene, as well as combinations thereof, may be used as the hydrocarbon compound. Liquid precursors may be used to deposit amorphous carbon films. A variety of gases such as hydrogen (H₂) and ammonia (NH₃), or combinations thereof, among others, may be added to the gas mixture, if desired to control the hydrogen ratio of the amorphous carbon layer. Argon (Ar), helium (He), and nitrogen (N₂) may be used to control the density and deposition rate of the amorphous carbon layer.

In general, the following deposition process parameters may be used to form the amorphous carbon layer 206. The process parameters range from a wafer temperature of about 100 degrees Celsius to about 500 degrees Celsius, a chamber pressure of about 2 Torr to about 20 Torr, a hydrocarbon gas (CₓH_{y}) flow rate of about 50 sccm to about 50,000 sccm (per 8 inch wafer—for example), a RF power of between about 3 W/in² to about 20 W/in², and a plate spacing of between about 200 mils to about 1,200 mils. The above process parameters provide a typical deposition rate for the amorphous carbon layer in the range of about 100 Angstroms/min to about 10,000 Angstroms/min and may be implemented on a 300 mm substrate in a deposition chamber available from Applied Materials, Inc. of Santa Clara, Calif. The thickness of the amorphous carbon layer 206 is variable, depending on the specific stage of processing. Typically, the amorphous carbon layer 206 may have a thickness in the range of about 500 Angstroms to about 10,000 Angstroms.

An ARC layer 208 may be deposited over the amorphous carbon layer 206 to suppress the reflections of the underlying layers and provide accurate pattern replication of the layer of photoresist. The ARC layer 208 may be conventionally formed on the amorphous carbon layer 206 using a variety of chemical vapor deposition (CVD) processes such as PECVD. In one embodiment, the ARC layer 208 may be graded. The ARC layer 208 may be formed by forming a plasma from a gaseous mixture of a carbon source, a silicon source, an oxygen source, and an inert gas. The silicon source may include silane, disilane, chlorosilane, dichlorosilane, trimethylsilane, tetramethylsilane, and combinations thereof. The silicon source may also include an organosilicon compounds such as tetraethoxysilane (TEOS), triethoxyfluorosilane (TEFS), diethoxymethylsilane (DEMS), 1,3,5,7-tetramethylcyclotetrasiloxane (TMCTS), dimethyldiethoxy silane (DMDE), octamethylcyclotetrasiloxane (OMCTS), and combinations thereof. The oxygen source may include oxygen (O₂), ozone (O₃), nitrous oxide (N₂O), carbon monoxide (CO), carbon dioxide (CO₂), water (H₂O), 2,3-butanedione, or combinations thereof. The inert gas may be selected from a group comprising argon, helium, neon, krypton, xenon, and combinations thereof. The carbon sources may be selected from a group comprising propylene (C₃H₆), propyne (C₃H₄), propane (C₃H₈), butane (C₄H₁₀), butylene (C₄H₈), butadiene (C₄H₆), acetelyne (C₂H₂), pentane, pentene, pentadiene, cyclopentane, cyclopentadiene, benzene, toluene, alpha-terpinene, phenol, cymene, norbornadiene, as well as combinations thereof.

In one embodiment, the gaseous mixture comprises silane (flow rate of about 10 sccm-about 2,000 sccm), carbon dioxide (flow rate of about 100 sccm-about 100,000 sccm), and helium flow rate of (about 0 sccm-about 10,000 sccm). The varying optical properties of the ARC layer 208 are achieved by varying the flow rates of the aforementioned gases. The ARC layer 208 may have a refractive index (n) in the range of about 1.0 to 2.2 and an absorption coefficient (k) in the range of about 0 to about 1.0 at wavelengths less than about 250 nm, thus making it suitable for use as an ARC at DUV wavelengths.

In one embodiment, the amorphous carbon layer 206 and ARC layer 208 may be formed in-situ in the same system or process chamber without breaking vacuum. The in-situ layer may be deposited under the same conditions as the amorphous carbon layer but a silicon source, such as trimethylsilane or silane, is added followed by an oxygen precursor. Flow modulation of the gases in the chamber allows for graded deposition of the in-situ layer.

To reduce or prevent pattern collapse, a hermetic oxide layer 210 is deposited on the ARC layer 208. The hermetic oxide layer 210 may be deposited within the same chamber as the ARC layer 208 and the amorphous carbon layer 206. In one embodiment, the hermetic oxide layer 210 may comprise silicon dioxide. The hermetic oxide layer 210 may be formed by introducing a silicon containing gas, an oxygen containing gas, and an inert gas into the processing chamber. In one embodiment, the silicon containing gas may comprise silane. Other silicon containing gases that may be utilized include disilane, chlorosilane, dichiorosilane, trimethylsilane, and tetramethylsilane, TEOS, TEFS, DEMS, TMCTS, DMDE, OMCTS, and combinations thereof. The silicon containing gas may be introduced to the processing chamber at a rate between about 50 sccm and about 100 sccm. The oxygen containing gas may include oxygen (O₂), ozone (O₃), nitrous oxide (N₂O), carbon monoxide (CO), carbon dioxide (CO₂), water (H₂O), 2,3-butanedione, or combinations thereof. The oxygen containing gas may be introduced to the processing chamber at a flow rate of about 9,000 sccm to about 10,000 sccm. The inert gas is selected from a group comprising argon, helium, neon, krypton, xenon, and combinations thereof. The inert gas may be introduced to the processing chamber at a flow rate of about 9,500 sccm to about 10,500 sccm. The ratio of silicon containing gas to carbon dioxide may be between about 0.005:1 to about 0.007:1.

The hermetic oxide layer 210 may be deposited utilizing either a single frequency RF bias to the showerhead or a dual frequency bias where both the showerhead and the substrate support are biased. In a single frequency process, the RF current may be between about 100 MHz to about 180 MHz. For the dual frequency process, the showerhead bias may be between about 100 MHz to about 180 MHz and the substrate support bias may be between about 30 MHz and about 180 MHz. The hermetic oxide layer 210 may be deposited to a thickness of between about 10 Angstroms to about 3,000 Angstroms. In one embodiment, the hermetic oxide layer 210 may be deposited to a thickness between about 20 Angstroms and about 55 Angstroms. The hermetic oxide layer 210, when deposited, may have a compressive stress.

After depositing the hermetic oxide layer 210, the hermetic oxide layer 210 may be exposed to an adhesion promoter, such as hexamethyldisilizane (HMDS), which serves to bond the photoresist 212 to the hermetic oxide layer 210. As shown in FIGS. 2B-2C, the photoresist 212 may be pattern exposed to create exposed regions 216 and unexposed regions 214 in the photoresist 212 that are removed by development. While the photoresist exemplified in the drawings is a positive photoresist whereby the exposed portions are removed, it is to be understood that a negative photoresist may be used whereby unexposed portions of the photoresist may be removed during development. After development, the developing solution may be removed by deionized water. The water droplets 220 that remain between the features 218 of the photoresist dry, but the capillary force of the water does not exceed the adhesion force of the photoresist to the hermetic oxide. Thus, the features 218 do not collapse.

Thereafter, the pattern defined by the features 218 may be transferred through the hermetic oxide layer 210, the ARC layer 208 and the amorphous carbon layer 206. The pattern may be transferred through the hermetic oxide layer 310 and the ARC layer 208 using a gas mixture comprising a hydrogen-containing fluorocarbon (CₓF_{y}H_{z}) and one or more gases selected from the group consisting of hydrogen (H₂), nitrogen (N₂), oxygen (O₂), argon (Ar), and helium (He). The amorphous carbon layer 206 may be etched using ozone, oxygen, or ammonia plasmas alone or in combination with hydrogen bromide (HBr), nitrogen (N₂), carbon tetrafluoride (CF₄), argon (Ar), and others. The layers may be etched in-situ with different process steps. In-situ should be broadly construed and includes, but is not limited to, in a given chamber, such as in a plasma chamber, or in a system, such as an integrated cluster tool arrangement, without exposing the material to intervening contamination environments, such as breaking vacuum between process steps or chambers within a tool. An in-situ process typically minimizes process time and possible contaminants compared to relocating the substrate to other processing chambers or areas.

### EXAMPLE 1

A hermetic oxide layer was deposited over a substrate having a layer stack consisting of a material layer, an amorphous carbon layer, and an ARC layer. The hermetic oxide layer was deposited at a temperature of 350 degrees Celsius and a pressure of 6 Torr. Process gases of 60 sccm silane and 9,900 sccm carbon dioxide were introduced into the chamber along with 10,000 sccm helium while the showerhead was biased with an RF frequency of 180 MHz and the substrate support was biased with an RF frequency of 180 MHz. The hermetic oxide layer was deposited to a thickness of 500 Angstroms. The hermetic oxide layer had tensile stress of 177 MPa when deposited. When the hermetic oxide layer was exposed to an atmosphere having 85 percent humidity at 85 degrees Celsius for 1 day, the oxide layer's stress changed to 176 MPa for a change in stress of 1 MPa. The hermetic oxide layer was stable and hence, the hermetic oxide layer did not fail under conditions designed to replicate deionized water rinsing.

### EXAMPLE 2

A hermetic oxide layer was deposited over a substrate having a layer stack consisting of a material layer, an amorphous carbon layer, and an ARC layer. The hermetic oxide layer was deposited at a temperature of 400 degrees Celsius and a pressure of 7 Torr. 50 sccm silane and 9,900 sccm carbon dioxide were introduced into the chamber along with 10,000 sccm helium while the showerhead was biased with an RF frequency of 140 MHz and the substrate support was biased with an RF frequency of 40 MHz. The hermetic oxide layer was deposited to a thickness of 2,741 Angstroms. The hermetic oxide layer had compressive stress of −214 MPa when deposited. When the hermetic oxide layer was exposed to an atmosphere having 85 percent humidity at 85 degrees Celsius for 1 day, the oxide layer's stress changed to −215 MPa for a change in stress of 1 MPa. The hermetic oxide layer was stable and hence, the hermetic oxide layer did not fail under conditions designed to replicate deionized water rinsing.

### EXAMPLE 3

A hermetic oxide layer was deposited over a substrate having a layer stack consisting of a material layer, an amorphous carbon layer, and an ARC layer. The hermetic oxide layer was deposited at a temperature of 400 degrees Celsius and a pressure of 7 Torr. 50 sccm silane and 9,900 sccm carbon dioxide were introduced into the chamber along with 10,000 sccm helium while the showerhead was biased with an RF frequency of 140 MHz and the substrate support was biased with an RF frequency of 40 MHz. The hermetic oxide layer was deposited to a thickness of 2,827 Angstroms. The hermetic oxide layer had compressive stress of −200 MPa when deposited. When the hermetic oxide layer was exposed to an atmosphere having 85 percent humidity at 85 degrees Celsius for 1 day, the oxide layer's stress changed to −201 MPa for a change in stress of 1 MPa. The hermetic oxide layer was stable and hence, the hermetic oxide layer did not fail under conditions designed to replicate deionized water rinsing.

### EXAMPLE 4

A hermetic oxide layer was deposited over a substrate having a layer stack consisting of a material layer, an amorphous carbon layer, and an ARC layer. The hermetic oxide layer was deposited at a temperature of 400 degrees Celsius and a pressure of 4 Torr. 50 sccm silane and 9,900 sccm carbon dioxide were introduced into the chamber along with 10,000 sccm helium while the showerhead was biased with an RF frequency of 140 MHz without applying a bias to the substrate support. The hermetic oxide layer was deposited to a thickness of 2,084 Angstroms. The hermetic oxide layer had compressive stress of −235 MPa when deposited. When the hermetic oxide layer was exposed to an atmosphere having 85 percent humidity at 85 degrees Celsius for 1 day, the oxide layer's stress changed to −236 MPa for a change in stress of 1 MPa. The hermetic oxide layer was stable and hence, the hermetic oxide layer did not fail under conditions designed to replicate deionized water rinsing.

### EXAMPLE 5

A hermetic oxide layer was deposited over a substrate having a layer stack consisting of a material layer, an amorphous carbon layer, and an ARC layer. The hermetic oxide layer was deposited at a temperature of 400 degrees Celsius and a pressure of 4 Torr. 50 sccm silane and 9,900 sccm carbon dioxide were introduced into the chamber along with 10,000 sccm helium while the showerhead was biased with an RF frequency of 140 MHz without applying a bias to the substrate support. The hermetic oxide layer was deposited to a thickness of 2,189 Angstroms. The hermetic oxide layer had compressive stress of −241 MPa when deposited. When the hermetic oxide layer was exposed to an atmosphere having 85 percent humidity at 85 degrees Celsius for 1 day, the oxide layer's stress changed to −242 MPa for a change in stress of 1 MPa. The hermetic oxide layer was stable and hence, the hermetic oxide layer did not fail under conditions designed to replicate deionized water rinsing.

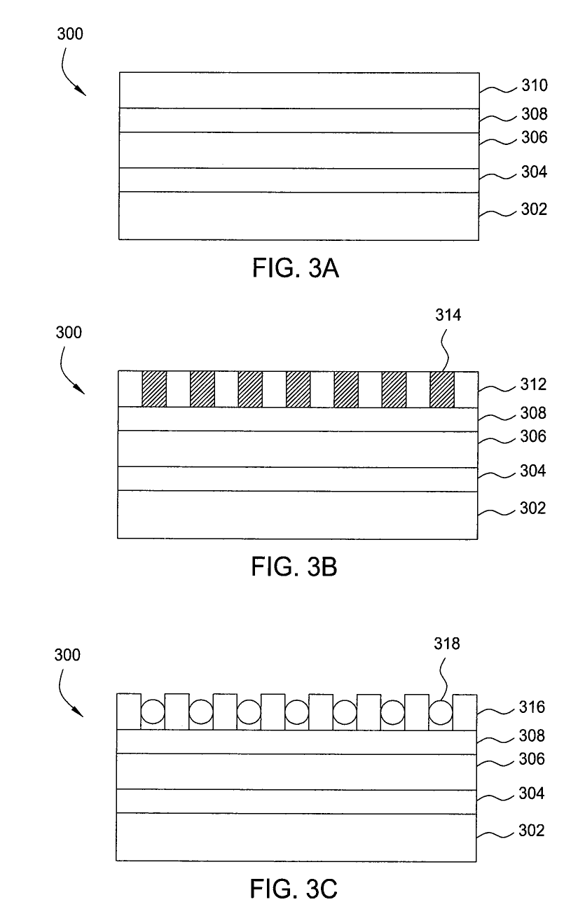

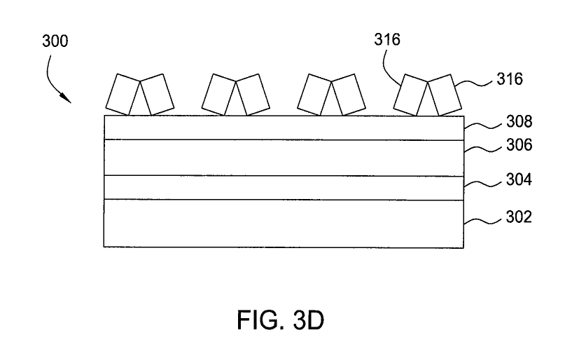

FIGS. 3A-3D (comparison) are schematic views of an integrated circuit 300 having a photoresist mask formed thereon at various stages of processing. The integrated circuit 300 may comprise a substrate 302, material layer 304, and ARC layer 306 as discussed above. A layer of photoresist 310 is formed on the ARC layer 308.

As shown in FIG. 3B, an image of a pattern may be introduced into the layer of photoresist 310 by pattern exposing such photoresist 310 to UV radiation to create exposed areas 314 and unexposed areas 312. The image of the pattern introduced in the layer of photoresist 310, is developed in an appropriate developer to define the features 316 of the pattern through such layer as shown in FIG. 3C. After development, the solution used to develop the photoresist 310 is rinsed from the integrated circuit using deionized water.

Water droplets 318 remain between the features 316. As the water droplets 318 dry, the capillary force of the water droplets 318 exceeds the adhesion force of the features 316 to the ARC layer 308. Because the capillary force exceeds the adhesion force, the features 316 coupled with a water droplet 318 collapse into each other such that pairs of features 316 collapse into each other as shown in FIG. 3D. The collapsed features 316 prevent patterning of the ARC layer 308, amorphous carbon layer 306, and material layer 304. Thus, the collapsed features 316 create a defective integrated circuit 300.

The features 316 collapse in spite of using an adhesion promoter because the water droplets weakly bond the adhesion promoter to the ARC layer 308. Unless the surface of the ARC layer 308 is completely dry (i.e., an ideal surface), the surface will have a hydroxyl terminated surface. When the adhesion promoter is deposited on the ARC layer 308, the silicon (in the case of HMDS) will weakly bond to the hydroxyl group. The adhesion promoter, because of the weak bonds, may not sufficiently adhere the features 316 to the ARC layer 308. Thus, the features 316 collapse.

### COMPARATIVE EXAMPLE

An oxide layer was deposited over a substrate having a layer stack consisting of a material layer, an amorphous carbon layer, and an ARC layer. The oxide layer was deposited at a temperature of 350 degrees Celsius and a pressure of 6 Torr. Process gases of 100 sccm silane and 9,000 sccm carbon dioxide were introduced into the chamber while the showerhead was biased with an RF frequency of 220 MHz without biasing the substrate support. The oxide layer was deposited to a thickness of 500 Angstroms. The oxide layer had tensile stress of 201 MPa. When the oxide layer was exposed to an atmosphere having 85 percent humidity at 85 degrees Celsius for 1 day, the oxide layer's stress changed to −51 MPa (i.e., compressive stress) for a change in stress of 251 MPa. The oxide layer was not stable and hence, the oxide layer failed under conditions designed to replicate deionized water rinsing.

By depositing a hermetic oxide layer between an ARC layer and a photoresist layer, the features of the photoresist mask formed by exposure and development resist collapse when deionized water rinses away the developing solution.

While the foregoing is directed to embodiments of the present invention, other and further embodiments of the invention may be devised without departing from the basic scope thereof, and the scope thereof is determined by the claims that follow.

1. A semiconductor process, comprising:
depositing an antireflective coating over a substrate in a processing chamber;
depositing a hermetic oxide layer on the antireflective coating using a gas mixture comprising a silicon containing gas and an oxygen containing gas, wherein the silicon containing gas and the oxygen containing gas are introduced into the processing chamber at a ratio of silicon containing gas to oxygen containing gas between about 0.005:1 to about 0.007:1; and
depositing a photoresist layer over the hermetic oxide layer.

2. The method of claim 1, further comprising:
exposing the hermetic oxide layer to an adhesion promoter.

3. The method of claim 2, wherein the adhesion promoter is hexamethyldisilizane (HMDS).

4. The method of claim 1, wherein the hermetic oxide layer is under compressive stress.

5. The method of claim 1, wherein the hermetic oxide comprises silicon dioxide.

6. The method of claim 1, wherein the oxygen containing gas is introduced into the processing chamber at a flow rate of about 9,000 sccm to about 10,000 sccm.

7. A semiconductor process, comprising:
depositing an amorphous carbon layer on a substrate disposed in a processing chamber;
depositing an antireflective coating on the amorphous carbon layer, wherein the antireflective coating comprises a carbon doped silicon oxide formed by generating a plasma from a gaseous mixture of a carbon source, a silicon source, and an oxygen source;
depositing a hermetic oxide layer on the antireflective coating using a gas mixture comprising a silicon containing gas and an oxygen containing gas;
depositing an adhesion promoter on the hermetic oxide layer; and
depositing a photoresist layer over the hermetic oxide layer.

8. The method of claim 7, wherein the oxygen containing gas comprises oxygen (O₂), ozone (O₃), nitrous oxide (N₂O), carbon monoxide (CO), carbon dioxide (CO₂), water (H₂O), 2,3-butanedione, and combinations thereof.

9. The method of claim 8, wherein the oxygen containing gas comprises carbon dioxide (CO₂).

10. The method of claim 9, wherein the depositing the hermetic oxide layer on the antireflective coating comprises introducing the gas mixture into the processing chamber at a ratio of silicon containing gas to carbon dioxide between about 0.005:1 to about 0.007:1.

11. The method of claim 8, wherein the oxygen containing gas is introduced into the processing chamber at a flow rate of about 9,000 sccm to about 10,000 sccm.

12. The method of claim 7, wherein the silicon containing gas comprises silane, disilane, chlorosilane, dichlorosilane, trimethylsilane, and tetramethylsilane, TEOS, TEFS, DEMS, TMCTS, DMDE, OMCTS, and combinations thereof.

13. The method of claim 7, wherein the gas mixture for depositing the hermetic oxide layer on the antireflective coating further comprises an inert gas selected from the group consisting of argon, helium, neon, krypton, xenon, and combinations thereof.

14. The method of claim 13, wherein the inert gas is introduced to the processing chamber at a flow rate of about 9,500 sccm to about 10,500 sccm.

15. The method of claim 7, wherein the hermetic oxide comprises silicon dioxide.

16. The method of claim 7, wherein the hermetic oxide layer is under compressive stress.

17. A semiconductor process, comprising:
depositing an amorphous carbon layer on a substrate disposed in a processing chamber;
depositing an antireflective coating on the amorphous carbon layer, wherein the antireflective coating comprises a carbon doped silicon oxide formed by generating a plasma from a gaseous mixture of a carbon source, a silicon source, and an oxygen source;
depositing a hermetic oxide layer on the antireflective coating using a gas mixture comprising a silicon containing gas and an oxygen containing gas, wherein the gas mixture is introduced into the processing chamber at a ratio of silicon containing gas to oxygen containing gas between about 0.005:1 to about 0.007:1; and
depositing and pattern exposing a photoresist layer over the hermetic oxide layer.

18. The method of claim 17, further comprising:
exposing the hermetic oxide layer to hexemethyldisilizane to deposit an adhesion promoter on the hermetic oxide layer.

19. The method of claim 17, wherein the oxygen containing gas comprises oxygen (O₂), ozone (O₃), nitrous oxide (N₂O), carbon monoxide (CO), carbon dioxide (CO₂), water (H₂O), 2,3-butanedione, and combinations thereof.

20. The method of claim 17, wherein the hermetic oxide comprises silicon dioxide.
